(19) United States
(12) Patent Application Publication
(10) Pub. No.: US 2004/0193975 A1
(43) Pub. Date: Sep. 30, 2004

(54) Method and an apparatus for transmit phase select

(76) Inventors: Tony M. Tarango, Folsom, CA (US); Felix A. Bachmeier, Folsom, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/400,975

(22) Filed: Mar. 26, 2003

(51) Int. Cl. G01R 31/28

(52) U.S. Cl. 714/724

(57) ABSTRACT

A method and an apparatus for transmit phase select are disclosed. In one embodiment, the method includes selecting one or more phases out of a set of phases of a clock, transmitting a data pattern in each of the selected phases, and receiving the loop-back data pattern. The techniques described herein can be used in screening out defective high-speed serial interface as well as design validation of the interface.

### FIELD OF INVENTION

The present invention relates generally to the field of integrated circuits, and more particularly, to testing high speed serial interface.

### BACKGROUND

As the speed of processor increases, the speed of serial interfaces of components in a computer system has to increase in order to keep up with the processor speed. The speed of a serial interface is typically several times of the speed of the computer system. For example, a 66 MHz computer system may have a component with serial interface operating at 1.5 GHz. To transfer data via a serial interface, a piece of data is divided into a number of segments, and all the segments are transmitted within one period of the computer system base clock. For example, a 64-bit data can be divided into eight segments, each segment having eight bits, to be transmitted through a serial interface within one period of the base clock of the computer system.

Although the operation of serial interface is more complicated than the operation of parallel interface, because of the high speed required, a serial interface is preferred over a parallel interface where wide and bulky cables are unwanted.

With the advent of high-speed data transfer via a serial interface, a more sophisticated and robust testing technique is necessary to fully test the high-speed serial interface. The traditional method of looping back signals to test a serial interface is inadequate for fully testing a high-speed serial interface because the speed of legacy testers is limited.

Currently, to test devices with high-speed serial interfaces, manufacturers either externally jitter or delay the signal with a module on a tester load-board, or replace legacy testers with expensive high-speed testers in order to keep up with the speed of the serial interface. Replacing legacy testers with high-speed testers significantly increases the cost of manufacturing high-speed serial interface because high-speed testers are very expensive. The second technique, which is to externally jitter or delay the signal with a module on the tester load-board, requires additional external components on the tester load-board. The external components occupy some of the tester channels, which otherwise can be used to test the pins of the device with the serial interface. Therefore, having external components occupy tester channels is not desirable.

Besides wasting tester channels on external components, the second technique also fails to provide full test coverage. This is because the second technique verifies that a data pattern is received properly for only a limited range of input phasing relative to a clock. Since the high-speed serial interface of an integrated circuit device is prone to manufacturing defects, it is necessary to test the interface of a device in all phases of the clock to screen out defective devices.

Another issue in testing a high-speed serial interface is the plesiochronous receiver of the interface. The receiver of the serial interface is plesiochronous when a host and a device do not use the same clock, and as a result, the data received has similar frequencies, but no phase relation. For example, in the system shown in FIG. 1, a hard disk drive 110 and an interface control hub 120 operate using different clock sources, namely clock source 115 and clock source 125, respectively. The receiver 118 of the hard disk drive uses edges on data received from the hub 120 to determine where to sample. Therefore, when testing the hard disk drive 110 by itself during manufacturing, it is necessary to test it with loop-back data in every phase of a clock to provide full test coverage of the serial receiver 118.

### BRIEF DESCRIPTION OF THE DRAWINGS

The present invention will be understood more fully from the detailed description that follows and from the accompanying drawings, which however, should not be taken to limit the invention to the specific embodiments shown, but are for explanation and understanding only.

FIG. 1 shows a hard disk drive coupled to an interface control hub within a computer system.

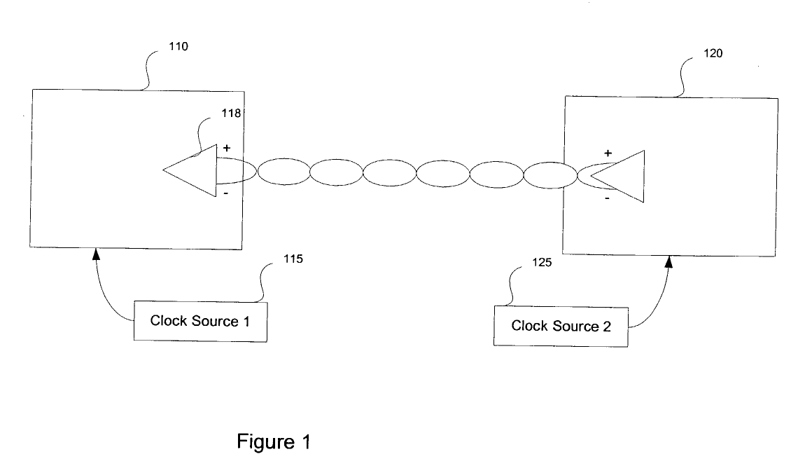

FIG. 2A shows an embodiment of a serial interface with data looped back.

FIG. 2B shows an embodiment of a serial interface with data looped back.

FIG. 3A shows an embodiment of a phase selection circuitry.

FIG. 3B shows an embodiment of circuitry for phase generation and selection.

FIG. 3C shows an embodiment of an oversampler.

FIG. 4 shows a transmission signal in various phases.

FIG. 5 shows a histogram with data of all eight phases superimposed.

FIG. 6 shows an embodiment of a computer system.

### DETAILED DESCRIPTION

A method and an apparatus for testing high-speed serial interface is described. In the following description, numerous details are set forth, such as specific circuit configurations, number of phases, number of flip-flops, etc., in order to provide a thorough understanding of the invention. It will be clear, however, to one skilled in the art, that these specific details may not be needed to practice the present invention.

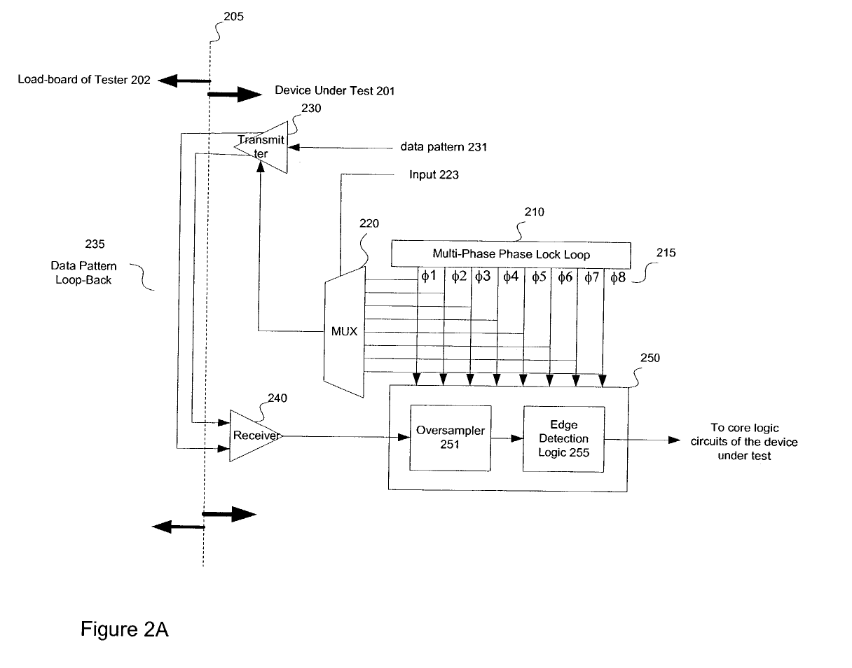

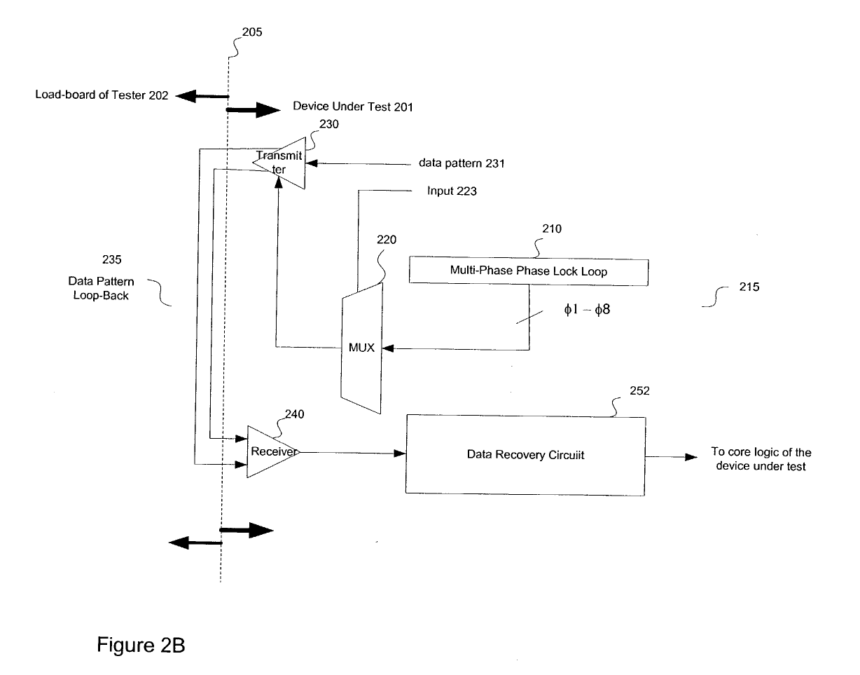

FIG. 2A shows an embodiment of a serial interface with data looped back. To the right of the dotted line 205 is the device under test 201, and to the left of the dotted line 205 is the load-board 202 coupled to a legacy tester (not shown). The device under test 201 has a high speed serial interface, which in one embodiment includes a multi-phase phase lock loop 210, a multiplexer 220, a transmitter 230, a receiver 240, and a data recovery circuit 250. The multi-phase phase lock loop 210 generates a set of phases 215. The set of phases 215 includes eight phases. The eight phases are phase-offset versions of the base clock (not shown), where the base clock defines the data rate. The phase-offset of these phases is one eighth of the period of the base clock. This allows the receiver 240 to over-sample the incoming data eight times within a bit-period. It should be appreciated that different numbers of phases can be generated in other embodiments, such as six, ten, sixteen, or the like.

During normal operation of the device 201, the transmitter 230 uses only a single phase of the base clock to transmit data. During testing of the device 201, the device 201 enters into a test mode, in which the transmitter 230 uses each of the eight phases 215 to transmit a data pattern 231. Different data patterns can be used in various embodiments of the present invention. Furthermore, it should be appreciated that the order in which the multiplexer 220 selects the phases may vary in different embodiments. In one embodiment, the phases are selected sequentially. In another embodiment, the phases are selected randomly. During testing of the device 201, one or more of the phases 215 are selected, depending on the degree of test coverage required. To achieve full test coverage, each phase is selected at least once during testing. However, the number of times a phase is selected during testing can vary in different embodiments of the present invention.

The set of phases 215 from the multi-phase phase lock loop 210 are input into a phase selection circuitry. In one embodiment, the phase selection circuitry includes an eight-input multiplexer 220. The multiplexer 220 selects a phase out of the set of phases 215 based on an input 223. In one embodiment, the input 223 is a three-bit number, ranges from 0 to 7. Different inputs can be used in other embodiments. Furthermore, the input 223 can be provided to the multiplexer 220 in various ways. In one embodiment, the input 223 is hard coded in a software program for testing the serial interface. In another embodiment, a software test program dynamically sets the input 223 during testing of the serial interface. In another embodiment, the input 223 is provided to the multiplexer 220 by hardware, such as a counter.

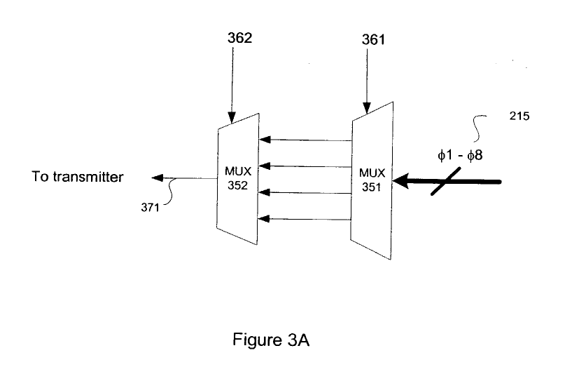

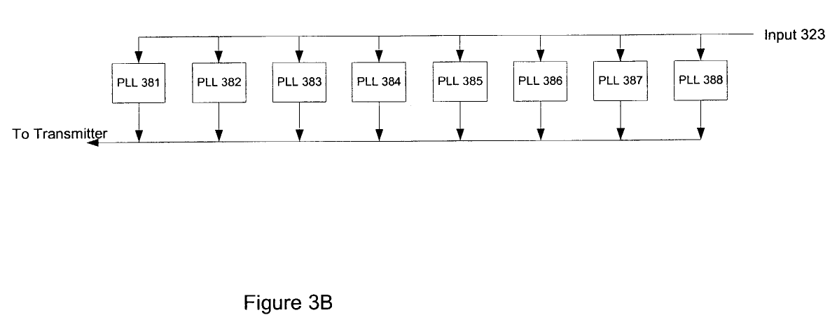

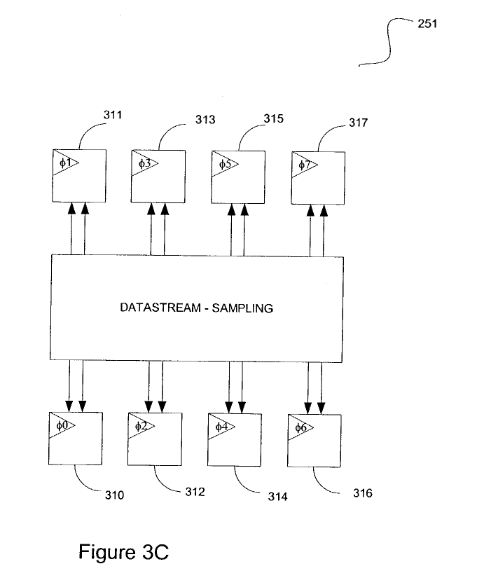

Moreover, it should be apparent that one of ordinary skill in the art can implement the phase selection circuitry with various circuit configurations. For example, in one embodiment, two four-input multiplexers can be used together to select a phase. FIG. 3A shows an alternate embodiment of a phase selection circuitry. Referring to FIG. 3A, a first multiplexer 351, controlled by a first input 361, selects half of the phases 215, which are input to a second multiplexer 352. The second multiplexer 352, controlled by a second input 362, selects a phase out of the phases from the first multiplexer 351. The selected phase 371 is output to the transmitter 230 in FIG. 2A. The implementations described here are by way of example only and are not intended to limit the scope and boundary of the claims.

FIG. 3B shows an alternate embodiment of a circuit for phase generation and selection. The circuitry in FIG. 3B includes eight phase lock loop blocks 381-383. Each phase lock loop block generates a distinct phase, which is a phase-offset version of the base clock (not shown). An input 323 is provided to all the phase lock loop blocks. The input 323 selectively enables one of the phase lock loop blocks to output the phase generated by the selected block to the transmitter 230 in FIG. 2A. The other phase lock loop blocks not selected are disabled by the input 323.

In addition to the selected phase, the transmitter 230 in FIG. 2A also receives a data pattern 231. The transmitter 230 transmits the data pattern 231 in the selected phase. Once the data pattern 231 is transmitted, the data pattern 231 is looped back to the receiver 240 of the device 201. In one embodiment, the data pattern loop-back path 235 is external to the device under test 201. The path of the data pattern loop-back 235 is provided by the load-board 202 coupled to a tester (not shown).

In one embodiment, the receiver 240 is coupled to a data recovery circuit 250 as shown in FIG. 2A. The data recovery circuit 250 samples the looped back data pattern recovered by the receiver 240 to recover the data pattern. Then the data recovery circuit 250 forwards the recovered data pattern to the core logic (not shown) of the device 201. One should appreciate that the data recovery circuit 250 is implemented in various ways in different embodiments.

Referring to FIG. 2A, one embodiment of data recovery circuit 250 includes an oversampler 251 and an edge-detection logic block 255. The looped back data pattern 235 received by the receiver 240 is input to the oversampler 251. The oversampler 251 also receives the set of phases 215 from the multi-phase phase lock loop 210. This is one of the advantages of the transmit phase select test mode described herein because there is no need to provide extra circuitry to generate the set of phases 215 for oversampling the loop-back data pattern received. Moreover, since the set of phases 215 provided to the multiplexer 220 and the oversampler 251 are the same, each phase of the set of phases 215 corresponds to an oversampling lane. When the transmit phase selection increments by one phase, it corresponds to a one phase shift at the receiver 240. This allows each oversampling lane to be tested, regardless of what the delay is from the transmitter 230 to the receiver 240. In contrast, an external module on tester load-board cannot test each oversampling lane of a serial interface because the jitter and delay technique can only test a limited range of input phasing relative to the clock. When the oversampler 251 receives the looped-back version of the data pattern 231 from the receiver 240, the oversampler 251 strobes the data pattern 231 in each phase of the set of phases 215. The oversampler 251 then outputs the strobed data to the edge-detection logic 255. The edge detection logic 255 determines a sampling point according to the sampled data from the oversampler 251.

An embodiment of the oversampler 251 is shown in FIG. 3C. Referring to FIG. 3C, the oversampler includes eight flip-flops 310-317. The loop-back data pattern received from the receiver 240 is latched into different flip-flops, where each flip-flop latches the data pattern in a different phase. By storing a data pattern in a flip-flop in each phase, the oversampler essentially strobes the data pattern in each phase. All oversampler strobed data for a given loop-back data pattern received from the receiver 240 is then output to the edge-detection logic (not shown) of the device 201 for further processing. It should be appreciated that the number of flip-flops used in the oversampler 251 varies in different embodiments of the present invention. For example, an embodiment can include six flip-flops when there are only six phases generated within the device.

FIG. 2B shows an alternate embodiment of a serial interface. To the right of the dotted line 205 is the device under test 201, and to the left of the dotted line 205 is the load-board 202 coupled to a legacy tester (not shown). The device under test 201 has a high speed serial interface, which in one embodiment includes a multi-phase phase lock loop 210, a multiplexer 220, a transmitter 230, a receiver 240, and a data recovery circuit 252. The multi-phase phase lock loop 210 generates a set of phases 215. The set of phases 215 are input to the multiplexer 220. The multiplexer 220 selects a phase out of the set of phases 215 according to the input 223. The selected phase is input to the transmitter 230. The transmitter 230 receives a data pattern 231 and transmits the data pattern 231 in the selected phase. The data pattern 231 is looped back and received by the receiver 240. The receiver 240 outputs the looped back data pattern to the data recovery circuit 252. The data recovery circuit 252 recovers the looped back data pattern by sampling the signal from the receiver 240. The data recovery circuit 252 then outputs the recovered data pattern to edge-detection logic circuits (not shown) of the device under test 201.

One embodiment of the data recovery circuit 252 includes analog and/or mixed signal circuitries to generate a second set of phases to sample the looped back data pattern through an analog mechanism. In one embodiment, the second set of phases is generated by a second phase lock loop within the data recovery circuit 252 and the second set of phases is distinct from the set 215 from the multi-phase phase lock loop 210. Using the second set of phases, the data recovery circuit 252 monitors the signal from the receiver 240 to derive another clock and to find an ideal sampling point. Since the data recovery circuit 252 has its own phase lock loop, it is not necessary to couple the phase lock loop 210 to the data recovery circuit 252 in this embodiment. After recovering the looped back data pattern, the data recovery circuit 252 outputs the recovered data pattern to the core logic (not shown) of the device 201.

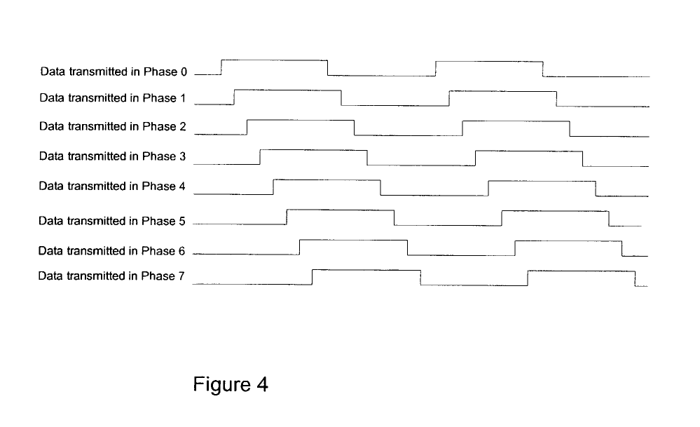

FIG. 4 shows an example of a data pattern transmitted in eight phases. The data pattern transmitted in each phase is a phase-offset version of the original data pattern. The capability of the device 201 to select any phase to transmit a data pattern allows testing of the serial interface in each phase. Moreover, the ability to select any phase from the transmit side of the interface allows the data recovery circuit to be fully exercised because the data recovery circuit can be forced to select different sampling points corresponding to the shift in the transmit data accomplished by the transmit phase select mechanism, regardless of the particular implementation of the data recovery circuit.

Another advantage of the built-in capability for phase selection is to eliminate the use of external components on the tester load-board to jitter or delay the transmitted signal. The circuit for phase selection is internal to the device 201. Therefore, it simplifies the tester load-board design and reduces the amount of control required from the tester. Moreover, by eliminating the external components, the tester channels previously occupied by the external components can be freed up to test the pins of the device 201 instead.

In addition, the built-in capability for phase selection enables the device to test its own high-speed serial interface. It, therefore, eliminates the need to replace legacy testers with expensive high-speed testers, which translates into significant savings of cost in high volume manufacturing of devices with high-speed serial interface.

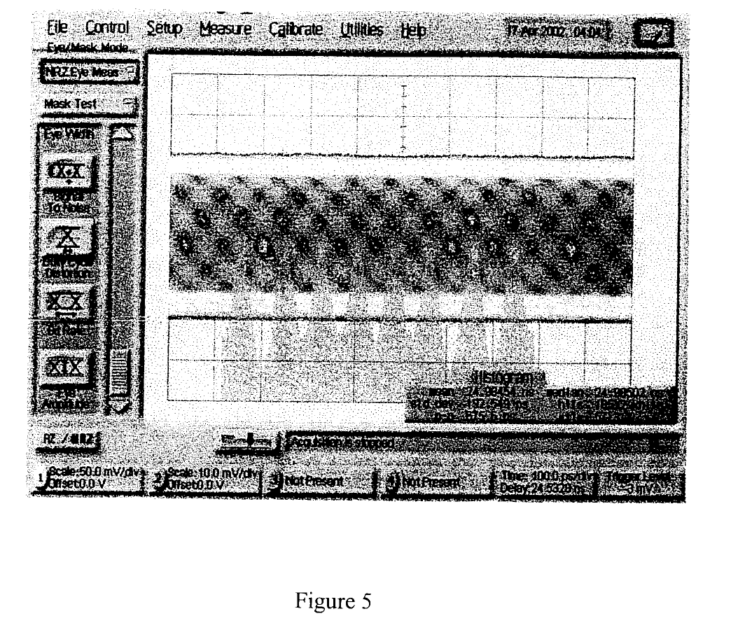

Besides applying the technique of transmit phase selection on device testing in high volume manufacturing, one can also use the circuit during design validation and debugging of the device 201 to ensure correct tolerance by the receiver 240 and the data recovery circuit 252. Since the multiplexer 220 can select each phase individually, one can observe the transmission of data pattern in each phase on an oscilloscope coupled to the load-board and the device under test. FIG. 5 shows an example of a histogram from an oscilloscope with data of all of the eight phases superimposed. In the histogram, the spacing between the peaks corresponds to the phase-offset within the device 201 under test. One can use the histogram to readily verify the phase-offset of the multi-phase phase lock loop 210 of the device 201. Therefore, the capability to select any phase on the transmit side of the interface is a useful feature in design validation and debugging of the device 201.

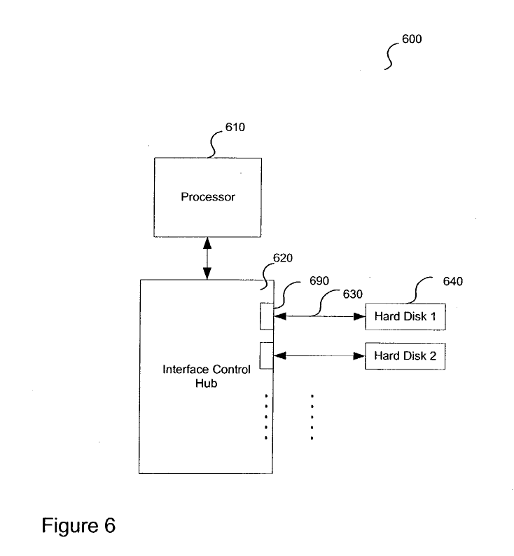

FIG. 6 shows an embodiment of a computer system. The computer system in FIG. 6 includes a processor 610, an interface control hub 620, a hard disk drive 640, and various buses coupling the components. The bus 630 coupling the interface controller hub 620 and the hard disk drive 640 is a serial bus. The interface controller hub 620 includes a serial interface 690 to transfer data to and from the serial bus 630. Other embodiments of the interface controller hub 620 include more than one serial interfaces, such as 2, 8, 32, etc. The serial interface 690 further includes a multiplexer, a transmitter, a receiver, a multi-phase phase lock loop circuit and a data recovery circuit. The multi-phase phase lock loop generates a set of phases, which are input to the multiplexer. The multiplexer can select any phase out of the set of phases. The multiplexer provides the selected phase to the transmitter to transmit a data pattern. The data pattern can be looped back and received by the receiver. The receiver then outputs the received data pattern to the data recovery circuit, which recovers the data pattern. In one embodiment, the data recovery circuit includes an oversampler. The oversampler receives the set of phases from the phase lock loop and samples the looped back data pattern in each phase of the set of phases. In an alternate embodiment, the data recovery circuit samples the looped back data pattern through analog mechanism. The data recovery circuit includes its own phase lock loop to monitor the looped back data and to derive another clock.

The foregoing discussion merely describes some exemplary embodiments of the present invention. One skilled in the art will readily recognize from such discussion, the accompanying drawings and the claims that various modifications can be made without departing from the spirit and scope of the invention.

We claim:

1. A method comprising:
selecting a first phase out of a plurality of phases of a clock;
transmitting a first data pattern in the first phase selected; and
receiving a looped back version of the first data pattern transmitted.

2. The method of claim 1, further comprising looping back the first data pattern transmitted.

3. The method of claim 1, further comprising generating the plurality of phases of the clock.

4. The method of claim 1, wherein the first phase is selected in response to an input.

5. The method of claim 4, wherein the input is provided by software.

6. The method of claim 4, wherein the input is provided by hardware.

7. The method of claim 4, further comprising receiving the plurality of phases of the clock and the input.

8. The method of claim 1, further comprising recovering the looped back version of the first data pattern received.

9. The method of claim 8, wherein recovering the looped back version of the first data pattern comprises latching the looped back version of the data pattern in a plurality of flip-flops in response to the plurality of phases of the clock.

10. The method of claim 8, wherein recovering the looped back version of the first data pattern comprises sampling the looped back version of the first data pattern through an analog mechanism.

11. The method of claim 1, further comprising:
selecting a second phase out of the plurality of phases of the clock;
transmitting a second data pattern in the second phase selected; and
receiving a looped back version of the second data pattern transmitted.

12. An apparatus comprising:
a multiplexer to select a phase out of a plurality of phases of a clock for output;
a transmitter, coupled to the multiplexer, to transmit a data pattern in the phase selected by the multiplexer, wherein the data pattern transmitted is looped back; and
a receiver to receive the data pattern looped back.

13. The apparatus of claim 11, further comprising a multi-phase phase lock loop circuit coupled to the multiplexer to generate the plurality of phases of the clock.

14. The apparatus of claim 12, wherein the multiplexer is operable to select the phase out of the plurality of phases from the multi-phase phase lock loop circuit in response to an input to the multiplexer.

15. The apparatus of claim 13, further comprising a data recovery circuit coupled to the receiver to recover the data pattern from the receiver.

16. The apparatus of claim 15, wherein the data recovery circuit comprises a plurality of flip-flops to latch the data pattern received from the receiver.

17. The apparatus of claim 16, wherein the plurality of flip-flops latch the data pattern received from the receiver in response to the plurality of phases of the clock.

18. The apparatus of claim 15, wherein the data recovery circuit comprises a second phase lock loop to sample the data pattern received from the receiver through an analog mechanism.

19. A device comprising:
a serial interface comprising
a multiplexer to select a phase out of a plurality of phases of a clock for output;
a transmitter, coupled to the multiplexer, to transmit a data pattern in the phase selected by the multiplexer, where the data pattern transmitted is looped back to the serial interface; and
a receiver to receive the data pattern looped back.

20. The device of claim 18, further comprising a multi-phase phase lock loop circuit coupled to the multiplexer to generate the plurality of phases of the clock.

21. The device of claim 18, wherein the multiplexer is operable to select the phase out of the plurality of phases from the multi-phase phase lock loop circuit in response to an input to the multiplexer.

22. The device of claim 19, further comprising a data recovery circuit coupled to the receiver to recover the data pattern from the receiver.

23. The device of claim 22, wherein the data recovery circuit comprises a plurality of flip-flops to latch the data pattern received from the receiver.

24. The device of claim 23, wherein the plurality of flip-flops latch the data pattern in response to the plurality of phases.

25. The device of claim 22, wherein the data recovery circuit comprises a second phase lock loop to sample the data pattern received from the receiver through an analog mechanism.

26. A computer system comprises:
a processor;
a bus;
at least one device coupled to the processor via the bus, the device comprising
a serial interface, wherein the serial interface includes a multiplexer to select a phase out of a plurality of phases of a clock for output;
a transmitter, coupled to the multiplexer, to transmit a data pattern in the phase selected by the multiplexer, wherein the data pattern transmitted is looped back to the serial interface; and
a receiver to receive the data pattern looped back.

27. The computer system in claim 26, further comprising a multi-phase phase lock loop circuit coupled to the multiplexer to generate the plurality of phases of the clock.

28. The computer system in claim 27, wherein the multiplexer is operable to select the phase out of the plurality of phases from the multi-phase phase lock loop circuit in response to an input to the multiplexer.

29. The computer system in claim 28, further comprising a data recovery circuit coupled to the receiver to recover the data pattern from the receiver.

30. The computer system in claim 29, wherein the data recovery circuit comprises a plurality of flip-flops to latch the data pattern received from the receiver.

31. The computer system in claim 30, wherein the plurality of flip-flops latch the data pattern received from the receiver in response to the plurality of phases.

32. The computer system in claim 29, wherein the data recovery circuit comprises a second phase lock loop to sample the data pattern received from the receiver through an analog mechanism.
